(19) United States
(12) Patent Application Publication
(10) Pub. No.: US 2010/0194450 A1
(43) Pub. Date: Aug. 5, 2010

(54) THIN-FILM TRANSISTOR CIRCUIT, DRIVING METHOD THEREOF, AND LIGHT-EMITTING DISPLAY APPARATUS

(75) Inventors: Hisae Shimizu, Tokyo (JP); Ryo Hayashi, Yokohama-shi (JP); Katsumi Abe, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/679,682

(22) PCT Filed: Nov. 11, 2008
(86) PCT No.: PCT/JP2008/070831

§ 371 Date: Mar. 24, 2010

(30) Foreign Application Priority Data
Nov. 21, 2007 (JP) 2007-301782

(51) Int. Cl. H03K 3/00; H01L 29/786; H01L 33/00

(52) U.S. Cl. 327/109; 257/57; 257/59; 257/E29.296; 257/E33.053

(57) ABSTRACT

In a light-emitting display apparatus including a plurality of pixels each including a light-emitting element and a driving circuit of the light-emitting element, and the driving circuit includes a plurality of thin-film transistors connected in parallel, a threshold voltage of the thin-film transistor reversibly changes according to a voltage applied between a gate and a source or between the gate and a drain of each of the thin-film transistors, by selecting and switching the plurality of thin-film transistors TFT11 to TFT13, the threshold voltage of the thin-film transistors for supplying a current to the light-emitting element is held within a predetermined range.

### TECHNICAL FIELD

The present invention relates to a light-emitting display apparatus using a light-emitting display element, a thin-film transistor circuit for driving the light-emitting display element, and a method for driving the thin-film transistor circuit. The present invention is particularly suitably used for a light-emitting display apparatus including pixels formed of organic electroluminescence (hereinafter abbreviated as “EL”) elements as light-emitting display elements and the driving circuits thereof in a matrix manner, and for a method for driving the active matrix.

### BACKGROUND ART

In recent years, research and development efforts are being made on an organic EL display using an organic EL element as a light-emitting element. Among organic EL displays, an active-matrix (hereinafter abbreviated as “AM”) type organic EL display including a separate driving circuit in each pixel is advantageous in order to suppress power consumption and realize high-quality images. This driving circuit includes a thin-film transistor (hereinafter abbreviated as “TFT”) formed on a substrate made of glass, plastic or the like. Among the components of the organic EL display, a portion primarily including the substrate and the driving circuit is referred to as a backplane.

As a TFT of a backplane intended for an organic EL display, hydrogenated amorphous silicon (hereinafter abbreviated as “a-Si:H”), polycrystalline silicon (hereinafter abbreviated as “p-Si”) and the like are under study. In addition, there has recently been proposed a TFT which uses a thin-film of an amorphous oxide semiconductor (hereinafter abbreviated as “AOS”) as the channel layer thereof. Examples of an AOS material include an oxide made of indium (In), gallium (Ga) and zinc (Zn) (amorphous-In—Ga—Zn—O, hereinafter abbreviated as “a-IGZO”) and an oxide made of zinc (Zn) and indium (In) (amorphous-Zn—In—O, hereinafter abbreviated as “a-ZIO”). A TFT using an amorphous oxide semiconductor as the channel layer thereof has a field effective mobility ten times or more as high as that of the a-Si:H TFT. Furthermore, high uniformity is considered available from the TFT due to the amorphous nature thereof. Consequently, these TFTs hold promise for use as TFTs of a backplane intended for a display.

Examples of technical issues concerning a backplane of an AM type organic EL display include an improvement in electron field-effect mobility in order to suppress a drive voltage and a TFT size, the suppression of a variation in TFT characteristics and, the suppression of change in TFT characteristics due to an electric stress attributable to current-carrying at the time of driving. An AOS-TFT has high electron field-effect mobility and high characteristic uniformity. Accordingly, it is possible to overcome the above-described two problems by using the AOS-TFT.

### DISCLOSURE OF THE INVENTION

However, a characteristic change due to an electric stress can also occur in the AOS-TFT. In particular, the problem of threshold voltage fluctuation due to continuous current-carrying and a recovery therefrom due to the stop of current-carrying remains to be solved.

It is intended in the disclosure of the present invention that the term “fluctuation” means “change” or “shift” of the threshold value from a first value to a second value.

An object of the present invention is to suppress a change in display quality resulting from a change in the characteristics of a TFT, such as an AOS-TFT, due to an electric stress and a recovery therefrom.

A method of driving a thin-film transistor circuit according to the present invention is characterized in that the thin-film transistor circuit comprises a plurality of thin-film transistors connected in parallel to an electric load, wherein a threshold voltage of the thin-film transistors fluctuates according to an electric stress applied between a gate and a source or between a gate and a drain of each of the thin-film transistors, and wherein the method comprises: a step of selecting and switching [one of] the plurality of thin-film transistors to suppress the fluctuation of the threshold voltage of the thin-film transistors to within a predetermined range.

A thin-film transistor circuit according to the present invention is characterized in that the thin-film transistor circuit comprises a plurality of thin-film transistors connected in parallel to an electric load, wherein a threshold voltage of the thin-film transistors fluctuates according to an electric stress applied between a gate and a source or between a gate and a drain of each of the thin-film transistors, and wherein the thin-film transistor circuit comprises: a unit for selecting and switching one of the plurality of thin-film transistors to suppress the fluctuation of the threshold voltage of the thin-film transistors to within a predetermined range.

A light-emitting display apparatus according to the present invention is characterized in that the light-emitting display apparatus comprises a plurality of pixels each including a light-emitting element and a driving circuit of the light-emitting element, wherein the driving circuit is included in each of the pixels, and comprises: a plurality of thin-film transistors connected in parallel to the light-emitting element, wherein a threshold voltage of the thin-film transistors fluctuates according to an electric stress applied between a gate and a source or between a gate and a drain of each of the thin-film transistors, and a unit for selecting and switching [one of] the plurality of thin-film transistors to hold the threshold voltage of the thin-film transistors supplying current to the light-emitting element within a predetermined range.

According to the present invention, it is possible to hold the threshold voltage of a TFT within a predetermined range.

Further features of the present invention will become apparent from the following description of exemplary embodiments with reference to the attached drawings.

### BRIEF DESCRIPTION OF THE DRAWINGS

FIG. 1 is a schematic view illustrating the configuration 1 (on an Si substrate) of an a-IGZO TFT according to the embodiment 1 of the present invention.

FIG. 2 is a graphical view illustrating the Id-Vg characteristic of the configuration 1 of the a-IGZO TFT according to the embodiment 1 of the present invention.

FIG. 3 is a graphical view illustrating a stress-induced threshold change in the configuration 1 of the a-IGZO TFT according to the embodiment 1 of the present invention.

FIG. 4 is a graphical view illustrating a characteristic of recovery from the change in the configuration 1 of the a-IGZO TFT according to the embodiment 1 of the present invention.

FIG. 5 is a graphical view illustrating the dependence of a stress change upon a gate voltage in the configuration 1 of the a-IGZO TFT according to the embodiment 1 of the present invention.

FIG. 6 is a schematic view illustrating the configuration 2 (on a glass substrate) of the a-IGZO TFT according to the embodiment 1 of the present invention.

FIG. 7 is a schematic view illustrating a circuit within a pixel of the embodiment 1 of the present invention.

FIG. 8 is a graphical view illustrating a threshold change when a TFT alternates between drive and resting.

FIG. 9 is a schematic view illustrating a circuit according to the embodiment 1 of the present invention.

FIG. 10 is a schematic view illustrating an exemplary embodiment of the present invention.

FIG. 11 is a timing chart according to an embodiment of the present invention.

FIGS. 12A and 12B are schematic views illustrating an example of connecting the terminals of a transistor in a resting state.

### BEST MODES FOR CARRYING OUT THE INVENTION

First, exemplary embodiments of the present invention will be described.

As a result of an in-depth study on the operating characteristics of an AOS-TFT, the present inventor et al. have gained the knowledge described below.

The characteristics of an AOS-TFT change due to an electric stress caused by current-carrying. A threshold voltage fluctuation is particularly characteristic.

This characteristic change is remarkable when a gate voltage is higher than a source voltage, and the amount of change tends to saturate with time. In addition, the AOS-TFT recovers from this characteristic change when current-carrying is stopped and the TFT is released from the electric stress. Thus, the AOS-TFT recovers to the characteristics before current-carrying. That is, the AOS-TFT has been invented based on the nature that the threshold voltage thereof changes reversibly when an electric stress is applied and removed. Note that the present invention is applicable to a TFT the threshold voltage of which changes reversibly due to an electric stress applied between a gate terminal and a source terminal or between a gate terminal and a drain terminal. Thus, the present invention is not limited to the AOS-TFT.

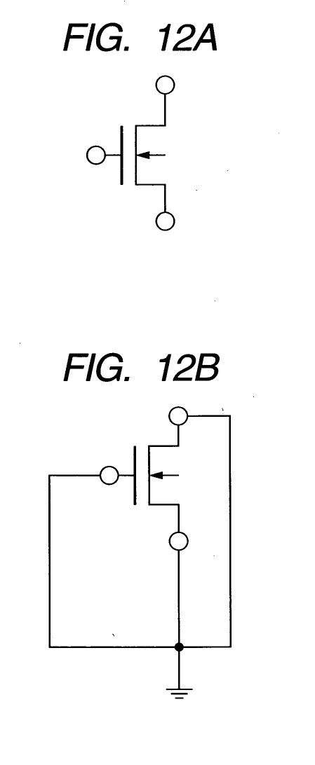

Here, “current-carrying” refers to a state in which a bias that causes a change in electric characteristics is applied to the gate, source and drain of a thin-film transistor. Specifically, “current-carrying” refers to a state of a potential difference being present at least between the gate and the source or between the gate and the drain. On the other hand, a “resting state” refers to a biased state of the gate, source and drain in which characteristics that have changed during current-carrying recover reversibly with the lapse of time. Specifically, “resting” refers to a state of a potential difference being not present between the gate and the source and between the gate and the drain, or the gate, source, and drain are in a floating state (see FIGS. 12A and 12B).

In the present invention, a plurality of AOS-TFT's are provided in the thin-film transistor circuit. Then, a TFT in use is placed in a resting state before the amount of change in characteristics due to an electric stress during current-carrying exceeds a predetermined reference value (while the amount of change is within a predetermined range), in order to recover the TFT from the characteristic change. On the other hand, those TFTs which have recovered from the characteristic change are selected as TFTs to be used, from among other TFTs which have been in a resting state up to then. In this way, TFTs which have recovered from a characteristic change due to an electric stress are selected and used.

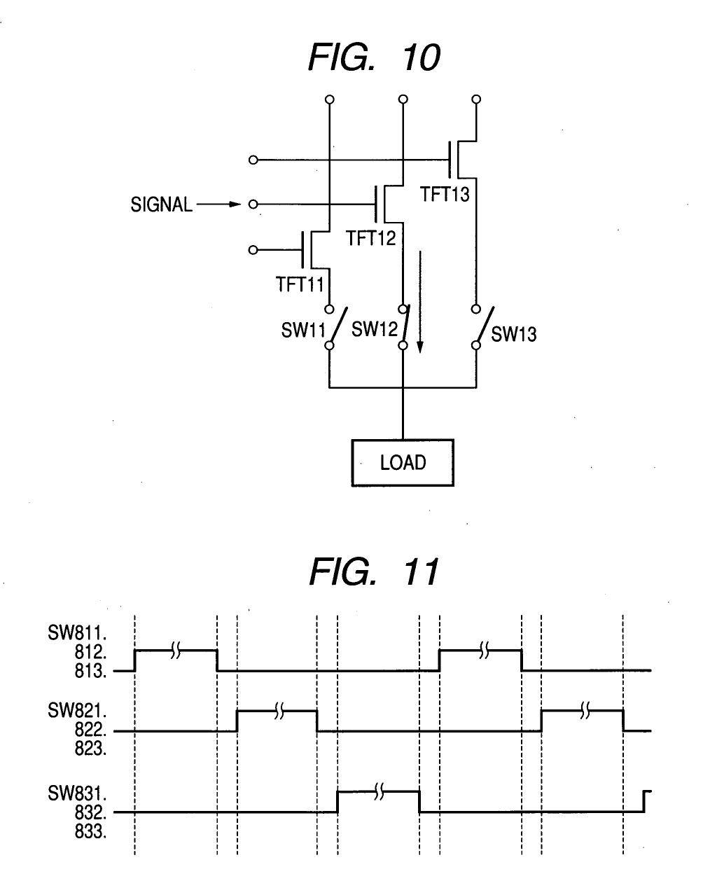

This will be described specifically using FIG. 10. There are prepared a plurality of TFTs 11 to 13 to serve as AOS-TFTs and to be connected in parallel. With a switch SW12 to serve as a switching unit turned on, a signal is applied to the gate of the TFT 12 to bias between the gate and the source thereof, and a current is flowed into a load. At this time, the characteristics (threshold value) of the TFT 12 begin to change due to an electric stress applied between the gate and source or between the gate and drain. However, a switch SW13 which has been in a resting state is turned on before the amount of characteristic change of the TFT2 exceeds a predetermined reference value, and a signal is applied to the TFT 13 to flow a current therefrom into the load. Simultaneously, the TFT 12 begins to recover to the characteristics before current-carrying when the TFT 12 is switched from a current-carrying state to a resting state. The characteristics (threshold value) of the TFT 13 also change due to an electric stress applied between the gate and source or between the gate and drain. Likewise, however, the switch SW11 which has been in a resting state is turned on before the amount of characteristic change of the TFT13 exceeds the predetermined reference value, and a signal is applied to the TFT 11 to flow a current therefrom into the load. Simultaneously, the TFT 13 is switched from a current-carrying state to a resting state.

Upon the recovery of characteristics of the TFT12, the switch SW12 is turned on to apply a signal to the TFT 12, and a current is flowed from the TFT 12 into the load. In this way, it is possible to flow a less-variable current into the load by selectively turning on the switches SW11 to SW13 and using any one of the TFT 11 to TFT 13. Note that a case is shown here in which one of the TFTs is selected and used. However, the number of TFTs may be set as appropriate, according to the length of a period required to recover characteristics. Thus, the number is set to 2 or larger as necessary. In addition, by connecting an even number of TFTs, e.g., four or not less than six TFTs in parallel and selectively and simultaneously turning on each pair of TFTs, it is possible to increase the amount of current to be flowed into the load.

Such a thin-film transistor circuit as described above can be used for a TFT designed to drive a pixel circuit for supplying a current to a light-emitting display element. That is, a plurality of AOS-TFTs are provided in a single pixel, and a TFT which has recovered from a characteristic change due to an electric stress is selected from among the AOS-TFTs and is used to drive the light-emitting display element. By not only switching such driving TFTs but also using a repetitive driving method, it is possible to hold the threshold voltage a TFT for driving the light-emitting display element within a predetermined range.

Furthermore, in the TFT driving method of the present embodiment, it is possible to determine a time of switching the TFT by monitoring the operating time or current-carrying time of a TFT and/or a voltage applied between a gate and a source and between a gate and drain during current-carrying. As will be described later, it is possible to previously know a characteristic change in a TFT due to an electric stress during current-carrying as a function of a current-carrying time and an applied voltage. Accordingly, it is possible to determine the time to make a switch, without directly measuring the characteristics of a driving TFT in a current-carrying or resting state.

In addition, for TFTs in a resting state, it is possible to ensure that the TFTs have no electric stress, by maintaining a potential between a gate and a source and a potential between a gate and a drain at the same level.

Hereinafter, as one embodiment of the present invention, a description will be made of an AM type organic EL display in which a driving circuit includes an AOS-TFT having an a-IGZO (amorphous oxide containing In, Ga and Zn) as the channel layer thereof and an organic EL element is a light-emitting display element. However, the present embodiment is also applicable to a light-emitting display apparatus having an AOS, other than the a-IGZO, as the semiconductor thereof, and to a display unit using a light-emitting element or a light-controlling element other than the organic EL element. Furthermore, in addition to the light-emitting display apparatus, the present embodiment is applicable to an AM (active-matrix) type device using an AOS-TFT, including a pressure sensor using a pressure-sensitive element and an optical sensor using a photosensitive element, and the same advantages can be obtained.

The term “amorphous” as used in the present invention means that distinct diffraction peaks attributable to a crystal structure are not observed in X-ray diffraction.

The AM type organic EL display of the present embodiment includes an organic EL element and a driving circuit in each pixel. Within the driving circuit, there are provided plural pairs of a driving AOS-TFT for controlling a current to be supplied to the organic EL element and a switch for changing the connection of the driving TFTs. If the threshold voltage change (or shift) due to an electric stress during current-carrying is determined as having exceeded a predetermined reference value, the driving TFT in question is placed in a resting state. Alternatively, a transistor the threshold voltage of which has fully recovered is selected from among remaining transistors which have been in a resting state up to then, and is used to drive a light-emitting display element. Thus, it is possible to suppress image degradation due to a threshold voltage fluctuation in an AOS-TFT.

As one method for evaluating the threshold voltage change (or shift) in a driving TFT in use and determining whether or not the threshold voltage of a driving TFT in a resting state has recovered, the integrated operating state time of the TFT is used.

### Embodiment 1

First, a description will be made of the basic characteristics of a TFT having an a-IGZO used in the present embodiment as the channel layer thereof.

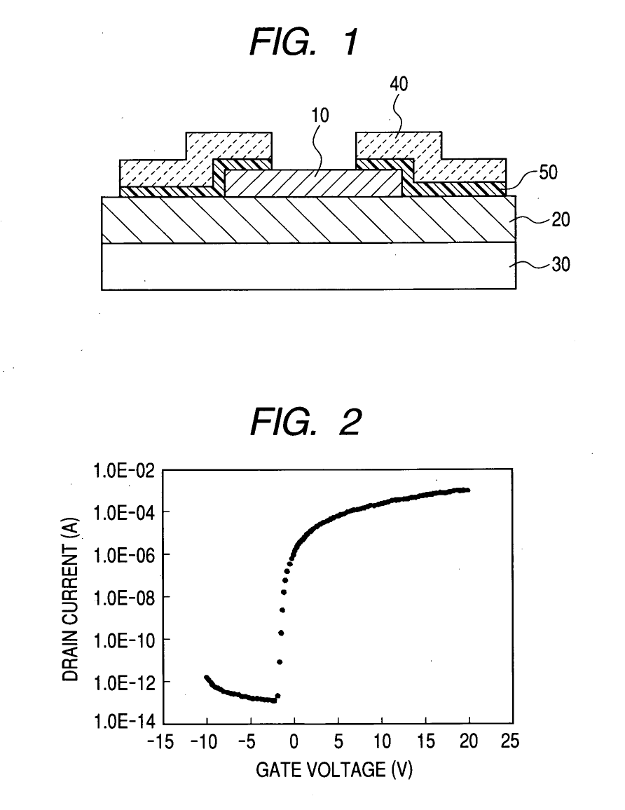

A method for fabricating the a-IGZO TFT is described hereinafter using FIG. 1.

As illustrated in FIG. 1, a 100 nm-thick thermally-oxidized SiO₂ insulating film 20 is formed on an Si substrate 30 heavily implanted with such an impurity as phosphorous or arsenic. Here, part of the Si substrate 30 composes a gate electrode.

After that, a-IGZO film 10 is formed to a thickness of 50 nm at room temperature by a sputter film-forming method using polycrystalline IGZO as a target. Next, the a-IGZO film 10 is subjected to patterning by wet etching using a photolithography method and dilute hydrochloric acid to form a channel layer.

After that, a resist is subjected to patterning by a photolithography method. Then, after forming films of Ti (5 nm) 50 and Au (40 nm) 40 by an EB vapor deposition method, Au/Ti source and drain electrodes are formed by a lift-off method.

In addition, 300° C., 1-hour annealing is performed.

Thus, it is possible to form the a-IGZO TFT illustrated in the cross-sectional view of FIG. 1.

Next, the electrical characteristics of the a-IGZO TFT obtained by the above-described method of fabrication will be described.

FIG. 2 is a graphical view illustrating the Id-Vg characteristic of the TFT. The TFT has a channel width of 80 μm, a channel length of 10 μm, a threshold voltage of −0.1 V, and a field effective mobility of 18 cm²/Vs. The field effective mobility is 10 times or greater than that of a usual a-Si:H TFT.

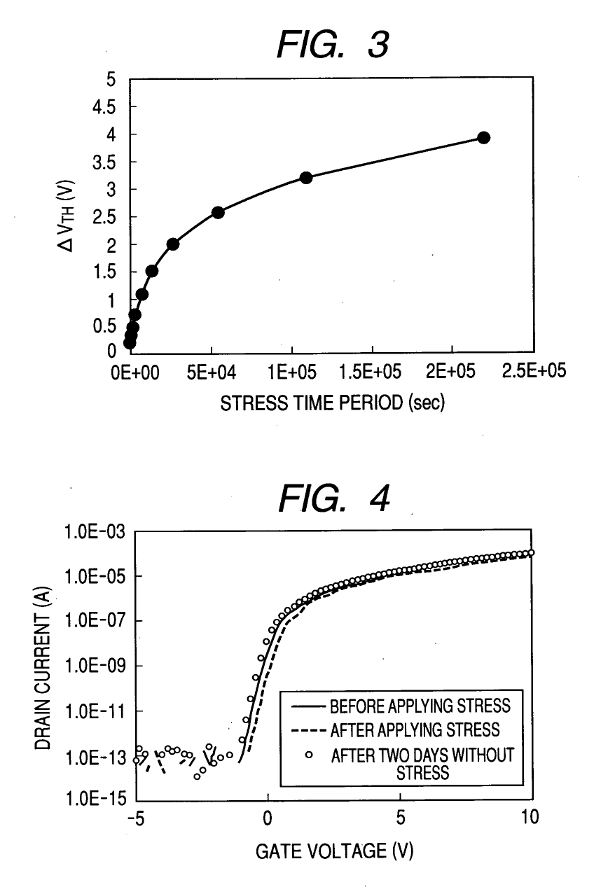

FIG. 3 illustrates the time change of a threshold voltage (ΔV_{TH}) in the TFT when the gate and drain thereof are short-circuited and a constant current of 27 μA is turned on between the drain and the source. The horizontal axis of FIG. 3 denotes a time period during which an electric stress is applied. At this time, the gate potential is kept higher than the source potential. In addition, the gate potential is the same as the drain potential. A notation of 5E+04, for example, in the horizontal axis of FIG. 3 denotes 5×10⁴.

In this case, a constant voltage is applied between the gate and drain terminals. In addition, a variable power source is provided in the source terminal so that a constant current flows between the drain and source terminals. That is, a current flowing between the drain and source terminals depends on a potential difference between the gate and source terminals. Therefore, the voltage of the power source provided in the source terminal is regulated so that the current flowing between the drain and source terminals is constant.

In addition, since the voltage of the gate terminal of the TFT is higher than that of the source terminal thereof, an electric stress is applied to the TFT. In this case, the threshold voltage of the TFT rises gradually. Accordingly, the potential difference between the gate and source terminals need to be increased, in order to keep constant the current flowing between the drain and source terminals. For this reason, the power source provided in the source terminal is regulated so that the voltage thereof decreases as the stress time period of FIG. 3 increases.

Note that FIG. 3 illustrates one example of a relationship between a stress time period and a threshold voltage when an electric stress is applied to a thin-film transistor using an amorphous oxide semiconductor. Accordingly, the relationship between the stress time period and the threshold voltage varies depending on the amorphous oxide semiconductor used and the conditions of stress application (voltage, temperature, etc.).

On the other hand, FIG. 4 illustrates transfer characteristics before and after an electric stress corresponding to a gate voltage of 12 V, a drain voltage of 6 V and a source voltage of 0 V is applied for 800 seconds to another a-IGZO TFT (channel width: 180 μm, channel length: 30 μm) formed using the above-described method. As in the example of FIG. 3, it is understood that the transfer characteristic curve moves in parallel in the forward direction due to the electric stress, and the threshold voltage increases. FIG. 4 also illustrates a transfer characteristic curve of the same TFT after operating state is stopped and then the TFT is left at rest for two days. It is understood that after the two days of rest, the transfer characteristic curve is nearly equal to that before applying the stress and the TFT has recovered from a characteristic change due to the electric stress.

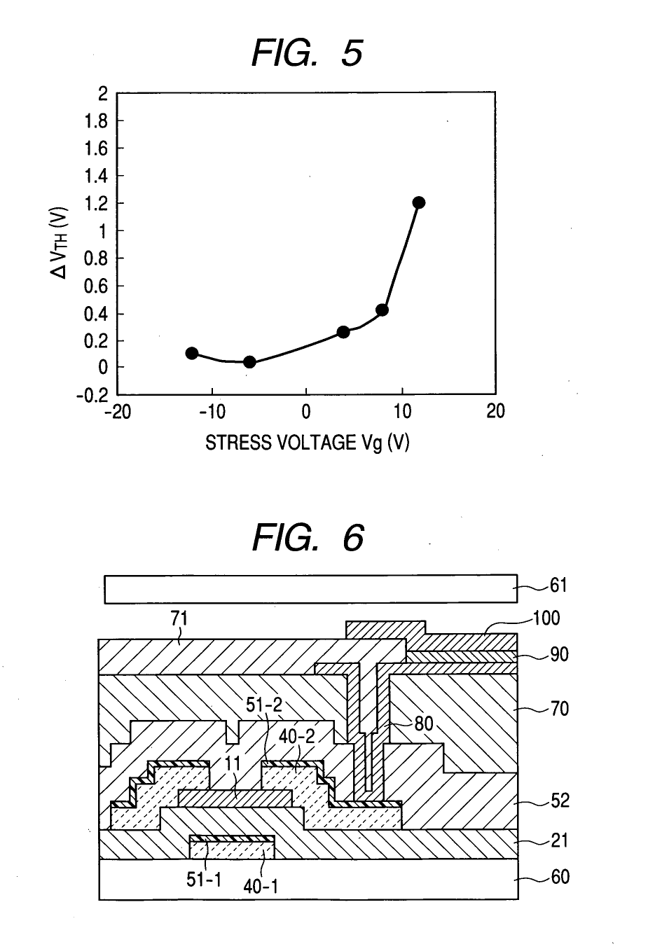

In addition, an electric stress is applied for 400 seconds to yet another a-IGZO TFT (channel width: 180 μm, channel length: 30 μm) formed using the above-described method, with the drain voltage set to 6 V, the source voltage set to a fixed value, and the gate voltage set to several different values. The gate voltage is varied in five ways, i.e., −12 V, −6 V, 4 V, 8 V and 12 V. FIG. 5 illustrates a threshold voltage fluctuation at this time due to an electric stress. From this figure, it is understood that the threshold voltage hardly fluctuates when the gate voltage is lower than the source voltage (lower than 0 V), and the fluctuation is largest when the gate voltage is higher than the source voltage and the drain voltage (12 V).

From FIGS. 3 and 5, it is understood that the threshold voltage fluctuation due to an electric stress that the TFT receives monotonically increases with respect to a voltage applied to the gate during operating state and a operating state time period. Therefore, the threshold voltage continues to increase if the operating state continues.

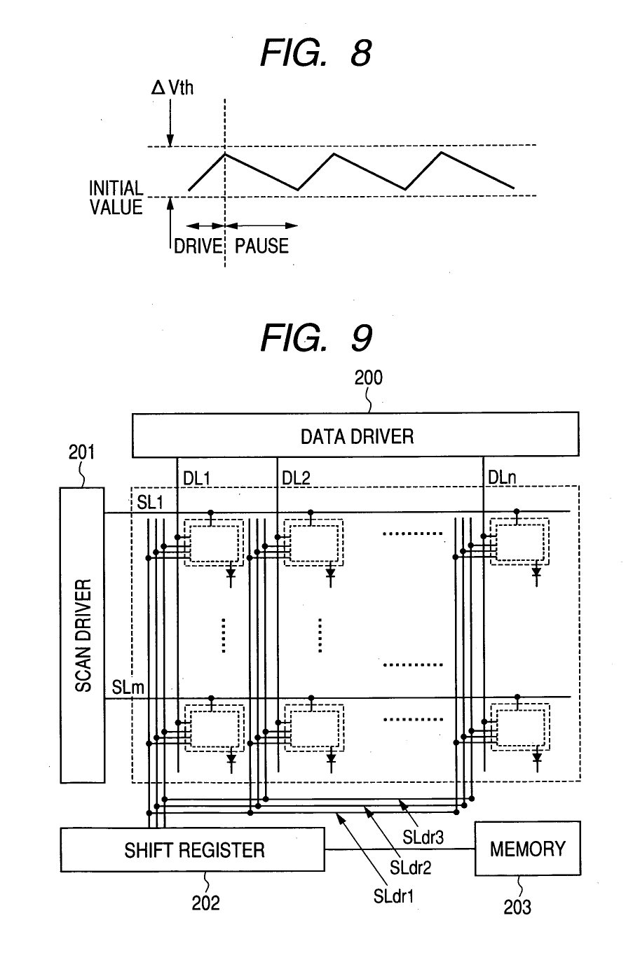

On the other hand, if the TFT after operating state is placed in a resting state by taking advantage of the nature that the threshold voltage shown in FIG. 4 recovers, it is possible to maintain the threshold voltage within a allowable range (FIG. 8).

In a resting state, the terminals are placed in a floating state. In addition, all of the three terminals are short-circuited and connected to a fixed potential.

Using the a-IGZO TFT exhibiting the above-described characteristics, an organic EL display illustrated in FIG. 6 is fabricated in such a way as described below.

First, an Mo/Ti laminated film made of Mo40-1 and Ti51-1 is formed on a glass substrate 60 by a vapor deposition method as a gate line and a gate electrode. Patterning is performed by etching.

Next, an SiO₂ film is formed by a sputtering method as an insulating layer 21. The pattern formation of the film is performed by a photolithography method and a wet etching method using buffered fluorinated acid.

Subsequently, an a-IGZO film 11 is formed by a sputtering method as a channel layer. The pattern formation of the film is performed by a photolithography method and a wet etching method using dilute hydrochloric acid.

Subsequently, an Mo/Ti laminated film made of Mo40-2 and Ti51-2 is formed by a vapor deposition method as a data interconnect and source/drain electrodes. Patterning is performed by etching.

Subsequently, an SiN/SiO₂ laminated film is formed as an interlayer insulating film. The pattern formation of the film is performed by a photolithography method and a dry etching method.

Subsequently, a photosensitive polyimide film is formed by a spin coat method as a planarized film. Since photosensitive polyimide is used, patterning can be performed by exposing the film by a photolithography method and separating the film.

Subsequently, an organic EL element is formed.

First, an ITO film 80 is formed by a sputtering method as an anode electrode. The pattern formation of the film is performed by a photolithography method and a wet etching method using an ITO-stripping solution or a dry etching method.

Subsequently, a photosensitive polyimide film 71 is formed by a spin coat method as an element-isolating film. Since photosensitive polyimide is used, patterning can be performed by exposing the film by a photolithography method and separating the film.

Subsequently, an organic film 90 is formed by a vapor deposition method as a light-emitting layer. The pattern formation of the film is performed using a metal mask.

Subsequently, an aluminum film is formed by a vapor deposition method as a cathode electrode 100. The pattern formation of the film is performed using a metal mask.

Finally, the subassembly being fabricated is glass-sealed using a glass substrate 61. The organic EL display can thus be fabricated (FIG. 6).

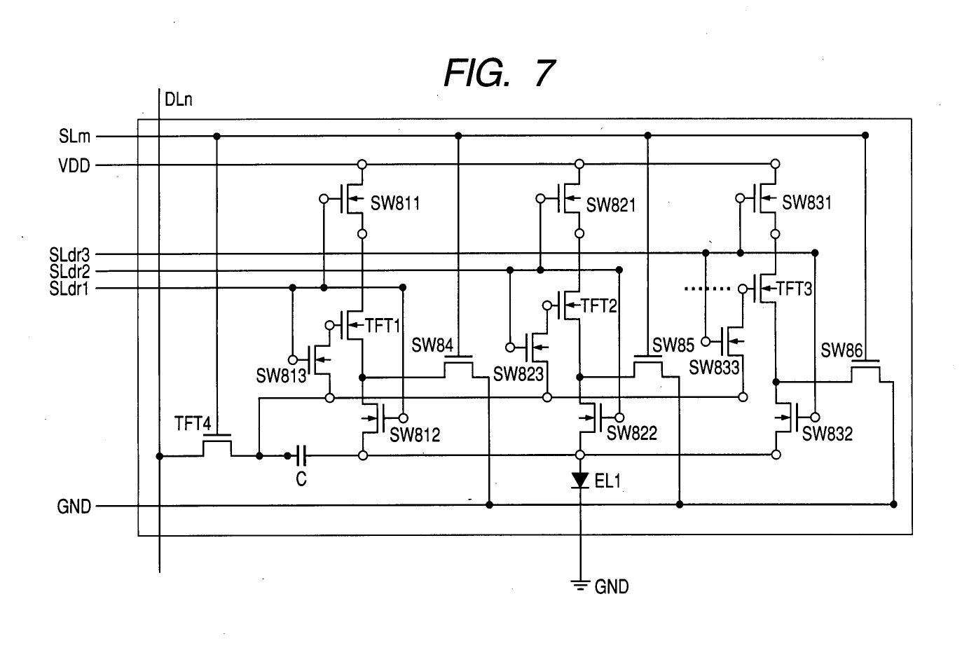

FIG. 7 illustrates a pixel circuit of the organic EL display of the present embodiment. In the present embodiment, the pixel circuit includes a switch TFT4 for loading data from an organic EL element EL1 and a signal line, driving transistors TFT1, TFT2 and TFT3, switching transistor groups SW811 to SW813, SW821 to SW823, and SW831 to SW833, a capacitor C connected to the gate-source potential of the driving transistors TFT1, TFT2 and TFT3, and switches SW84 to SW86 for grounding the sources of the TFT1, TFT2 and TFT3.

In a driving transistor within the pixel circuit, a “operating state” takes place during a period in which the driving transistor is connected in series with the organic EL element, while a “resting state” is realized during a period in which the driving transistor is electrically disconnected from the organic EL element.

FIG. 11 is a timing chart of control signals applied to the gates of the switching transistors 811 to 832. The SW811, SW812 and SW813 are correctively on/off-controlled by a control signal SLdr1. Likewise, the SW821, SW822 and SW823 are correctively on/off-controlled by a control signal SLdr2, and the SW831, SW832 and SW833 are correctively on/off-controlled by a control signal SLdr3. When the control signal SLdr1 is at an H level, i.e., the SW811, SW812 and SW813 are on, the TFT1 is connected in series with the organic EL element to govern current supply to the organic EL element. On the other hand, the TFT2 and TFT3 are disconnected from the organic EL element and in a resting state during that period. A period during which a current is supplied to the organic EL element is a period of “operating state” and, naturally, an electric stress that causes a characteristic change in a transistor is applied.

On the other hand, when a TFT is in a resting state, the gate, source and drain terminals thereof may be in a floating state. Alternatively, the gate, source and drain are preferably short-circuited and set to a fixed potential, for example, to the GND. In that case, there arises the need for additional switching transistors.

Next, the operation of the pixel circuit will be described. Although, only one pixel is taken up here to describe the operation thereof, the same holds true with other pixels. As driving TFTs, there are provided the TFT1 to TFT3, which alternate between drive and resting states in the order in which the TFTs are numbered.

Now, it is assumed that the TFT2 is selected as a driving TFT for supplying a current to the organic EL1. The TFT2 receives data as a gate voltage from a signal line on a frame-by-frame basis, and causes the organic EL1 to emit light at a predetermined brightness level. An electric stress as large as an applied voltage is incrementally applied to the TFT2 along with the lapse of display time. As a result, the threshold value of the TFT2 shifts monotonously.

Here, if a determination can be made that the threshold change of the TFT2 has exceeded a predetermined reference value, the TFT2 is placed in a resting state at the time. Alternatively, the TFT3 which has been in a resting state is used in the next frame to supply a current to the organic EL. Note here that the predetermined reference value is decided according to a threshold change in a TFT used for drive derived from a voltage to be applied and a time period of application.

After a lapse of further time, the TFT3 is placed in a resting state this time, as in the above-described case, at the moment the threshold value thereof is determined to have exceeded the reference value. Then the TFT1 is used as a driving TFT.

In a resting state, the three terminals of a TFT are placed in a floating state or connected to the same potential.

Note that control lines SL1 to SLm turn on switching transistors SW84, SW85 and SW86 in a writing period within a single frame. Scanning signals are sequentially applied to the control lines by a scanning driver 201. Accordingly, the source potential of a selected driving transistor is short-circuited to the GND while writing a data signal between the gate and source of the driving transistor by a data driver 200 through control lines DL1 to DLn. The control signal SLdr2 is set to an H level, the control signals SLdr1 and SLdr3 are set to an L level, the TFT2 is placed in a connected state, and the TFT1 and TFT3 are placed in a floating state. The TFT4 is turned on to write data into the capacitor C and the parasitic capacitor of the gate of the TFT2. Next, the switching transistors 84, 85 and 86 are turned off in a period in which the organic EL1 emits light, so that the source of the driving transistor TFT2 is connected in series with the organic EL only. Consequently, a current corresponding to the gate potential of the TFT2, into which the data is written, flows into the organic EL1 through the driving transistor TFT2. In a period of data writing, the control signals SLdr1 and SLdr3 of the driving transistors TFT1 and TFT3 are at an L level throughout the period of light emission of the EL. Therefore, the gate, source and drain maintain a floating state, i.e., a resting state.

Switching between a operating state and a resting state is controlled by a shift register 202 and a memory (serving as a storage device) 203 arranged in the peripheral part of pixels illustrated in FIG. 9. The memory 203 integrates the operating state time period of the driving transistors TFT1 to TFT3. If the integrated time of a TFT being driven exceeds a reference value, the shift register 202 transmits a signal for governing selection of the operating state or resting state of the TFT1 to TFT3 to a pixel area. In FIG. 9, the circuit is configured so that one of the TFT1 to TFT3 is selected by the shift register 202 for all pixels collectively. The above-described reference value differs depending on the purpose of use of a light-emitting display apparatus. For example, if the display apparatus has many steadily-lit pixels and includes pixels responsible for continuously providing high-brightness display like a monitor for a personal computer, the reference value of an integrated time is set to a small value. On the other hand, if the display apparatus deals with many movie displays like a television set, the reference value of an integrated time is set to a large value since an average drive current flowing through pixels decreases. Alternatively, it is possible to switch the TFTs for each frame or for each preset number of frames, without setting a reference value.

Note that it is not always necessary to select one of the TFT1 to TFT3 by the shift register for all pixels collectively. For example, the memory and the shift register may be separately provided to perform control, so that a change-over timing differs between one and the other parts of the pixel area.

The signals lines SLdr1, SLdr2 and SLdr3 in FIG. 7 lead from the shift register 202.

Here, time is used to determine a timing for switching between operating state and resting. Alternatively, it is possible to monitor an applied voltage or a threshold voltage to use the voltage for the timing.

In FIG. 7, there is shown a case in which the circuit has three driving transistors. It is possible, however, to reduce the number of spare TFTs to one if TFTs having a short recovery time are used. In this case, two driving TFTs will be enough for one pixel.

By performing the operations described heretofore, the organic EL display of the present embodiment enables an AOS-TFT in a state of being constantly refreshed against an electric stress to be used as a driving TFT. As a result, it is possible to suppress image degradation due to a threshold voltage fluctuation attributable to an electric stress on the TFT.

Note that the switch groups SW811 to SW813, SW821 to SW823, and SW831 to SW 833 can also be formed using an a-IGZO TFT. The switch groups SW811 to SW814, SW821 to SW824, and SW831 to 834 work as switches. Therefore, even if the threshold voltages thereof shift, the switches can still be driven if the drive voltages thereof are previously set to a predetermined value. Accordingly, there is no need to apply an electric stress to the switch groups.

The present invention is applied to a light-emitting apparatus in which the driving circuit of a light-emitting element has a TFT and, more particularly, to a light-emitting apparatus including an AOS-TFT having an AOS as the channel layer thereof. In addition to the light-emitting display apparatus, the present invention can also be applied to an AM (Active-Matrix) type device using an AOS-TFT, including a pressure sensor using a pressure-sensitive element and an optical sensor using a photosensitive element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-301782, filed Nov. 21, 2007, which is hereby incorporated by reference herein in its entirety.

1. A driving method of a thin film transistor circuit that includes a plurality of parallel thin film transistors connected to an electric load, wherein a threshold voltage of a thin film transistor fluctuates according to an electric stress applied between a source and a gate of the thin film transistor or between the gate and a drain of the thin film transistor, and wherein the method comprises:
selecting and switching one of the plurality of thin film transistors, to suppress a fluctuation of the threshold voltage of the thin film transistor, within a predetermined range.

2. The driving method of a thin film transistor circuit according to claim 1, wherein a non-selected thin film transistor is set at a resting state without the electric stress being applied thereto.

3. The driving method of a thin film transistor circuit according to claim 2, wherein a thin film transistor set at the resting state has a gate, a source, and a drain held at a same potential or in a floating state.

4. The driving method of a thin film transistor circuit according to claim 1, wherein the switching of the one of the plurality of thin film transistors is determined based on a time period of applying a voltage between a gate and a source of the one of the plurality of thin film transistors, or between the gate and a drain of the one of the plurality of thin film transistors.

5. The driving method of a thin film transistor circuit according to claim 1, wherein the switching of the one of the plurality of thin film transistors is determined based on a voltage applied between a gate and a source of the one of the plurality of thin film transistors, or between the gate and a drain of the one of the plurality of thin film transistors.

6. The driving method of a thin film transistor circuit according to claim 4, wherein the time period of applying the voltage between the gate and the source of the one of the plurality of thin film transistors, or between the gate and the drain of the one of the plurality of thin film transistors, at an operating state is stored, and a time period in which the one of the plurality of thin film transistors stays at a resting state is stored.

7. A thin film transistor circuit comprising:
a plurality of thin film transistors connected in parallel to an electric load, wherein a threshold voltage of a thin film transistor fluctuates according to an electric stress applied between a source and a gate or between the gate and a drain of the thin film transistor; and
a unit for selecting and switching one of the plurality of thin film transistors, to suppress a fluctuation of the threshold voltage of the one of the plurality of thin film transistors, within a predetermined range.

8. The thin film transistor circuit according to claim 7, wherein a non-selected thin film transistor is set at a resting state without the electric stress being applied thereto.

9. The thin film transistor circuit according to claim 7, wherein each thin film transistor has a channel layer formed of an amorphous oxide semiconductor.

10. A light emitting display apparatus comprising a plurality of pixels each including a light emitting element and a driving circuit of the light emitting element,
wherein the driving circuit is included in each of the pixels and includes:
a plurality of thin film transistors connected in parallel to the light emitting element, wherein a threshold voltage of each thin film transistor fluctuates according to an electric stress applied between a source and a gate of the thin film transistor or between the gate and a drain of the thin film transistor, and
an unit for selecting and switching one of the plurality of thin film transistors, to hold the threshold voltage of that thin film transistor, within a predetermined range.

11. The light emitting display apparatus according to claim 10, wherein a non-selected thin film transistor is set at a resting state without the electric stress being applied thereto.

12. The light emitting display apparatus according to claim 10, wherein each thin film transistor has a channel layer formed of an amorphous oxide semiconductor.
